(19) United States
(12) Patent Application Publication
(10) Pub. No.: US 2011/0012685 A1
(43) Pub. Date: Jan. 20, 2011

(54) Wide-band Low-voltage IQ-generating Ring-oscillator-based CMOS VCO

(76) Inventors: Hamid Partovi, Los Altos, CA (US); Luca Ravezzi, San Francisco, CA (US)

Correspondence Address: JONES DAY, 222 EAST 41ST ST, NEW YORK, NY, 10017, US

(21) Appl. No.: 12/684,164

(22) Filed: Jan. 8, 2010

Related U.S. Application Data
(60) Provisional application No. 61/143,671, filed on Jan. 9, 2009.

(51) Int. Cl. H03K 3/03

(52) U.S. Cl. 331/57

(57) ABSTRACT

A voltage controlled oscillator circuit includes first and second power rails, a control voltage rail, an input terminal, and an output terminal. A plurality of domino stages are series connected in a ring, with each of the domino stages being connected across the first and second power rails and being responsive to the control voltage rail. A plurality of feedback paths is provided with each path connected to enable one of the plurality of domino stages to input a feedback output signal to a preceding serially connected domino stage. A reset signal is asserted to place the domino stages in a post charge state and deasserted to allow the domino stages to begin producing an oscillating signal.

### CROSS-REFERENCE TO RELATED APPLICATIONS

The present application claims priority from U.S. application Ser. No. 61/143,671 filed Jan. 9, 2009, and entitled Wide-band Low-Voltage IQ-generating Ring-oscillator-based CMOS VCO, the entirety of which is hereby incorporated by reference for all purposes.

### BACKGROUND

In U.S. Pat. No. 4,985,643 a speed enhancement technique for CMOS circuits is disclosed. In the series of logic stages, nodes in the signal path of a pulse are set by preceding logic stages, then reset by feedback from subsequent logic stages. This eliminates the capacitive burden of resetting any given node from the input signal to allow substantially all of the input signal to be employed in setting the nodes to an active state rather than wasting part of the signal in turning off the reset path. The technique is illustrated as applied to RAM circuits.

### SUMMARY

A novel VCO topology based on Post-charged circuit principles is herein disclosed. Unlike the generic ring-oscillator VCO (RO-VCO) known in the art, which is formed by an odd number of inverting buffers, the proposed Post-charged VCO (PC-VCO) comprises any number of non-inverting stages.

The minimum oscillation period of the disclosed PC-VCO equals the delay through two non-inverting domino stages with excellent duty-cycle. The PC-VCO can also generate In- and Quadrature-phase clocks with high accuracy. Neither such high oscillation frequency nor the generation of I and Q phases are (easily) attainable with standard CMOS ring-oscillators.

### BRIEF DESCRIPTION OF THE DRAWINGS

For the present invention to be easily understood and readily practiced, the present invention will now be described, for purposes of illustration and not limitation, in conjunction with the following figures.

FIG. 1 illustrates a voltage controlled oscillator (VCO) constructed of four unit delay elements (each element also referred to as a non-inverting domino stage or domino buffer) connected in a ring according to the teachings of the present invention.

FIGS. 2 and 3 illustrate waveforms produced by the four-element VCO shown in FIG. 1 from de-assertion of reset and when in sustained oscillation, respectively.

FIG. 4 illustrates a circuit for using the output of the VCO shown in FIG. 1 to produce a full-rate differential clock.

FIG. 5 illustrates a circuit for using the output of the VCO of FIG. 1 to produce In-phase and Quadrature-phase clocks.

### DETAILED DESCRIPTION

The following describes a preferred embodiment of our invention. One possessing ordinary skill in the art will understand that the given assumptions are not limiting, and that various parameters can be varied while still practicing the disclosed invention.

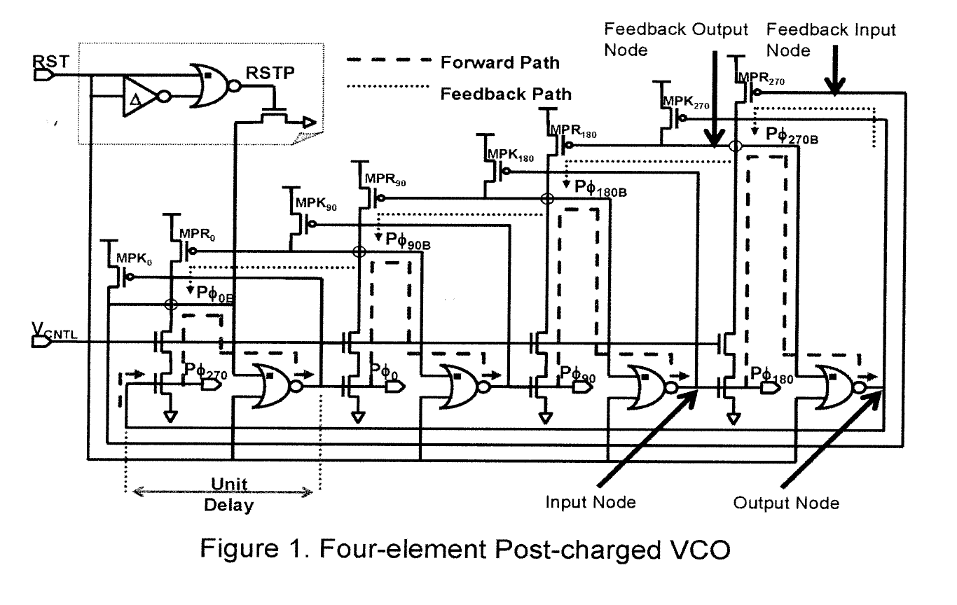

FIG. 1 depicts a four-element PC-VCO. As will be apparent to one possessing ordinary skill in the art, the number of elements is chosen here for the purpose of example but should be greater than or equal to two. For highest operating frequency, assume V_{CNTL}=V_{DD}, though our invention functions if V_{CNTL} is set to other values. With reset signal, RST, asserted, nodes Pφ₀, Pφ₉₀, Pφ₁₈₀, Pφ₂₇₀ are at ground, and nodes Pφ^{0B}, Pφ_{90B}, Pφ_{180B}, Pφ_{270B} are weakly held at V_{DD} by keeper transistors MPK₀, MPK₉₀, MPK₁₈₀, MPK₂₇₀.

On the falling edge of RST, the NOR gates are “enabled,” and contemporaneously, a short, high-going pulse is generated at node RSTP, which causes Pφ₀ to rise. This rising edge at node Pφ₀ discharges the weakly-held Pφ_{90B} to ground. Pφ₉₀ rises, and contemporaneously, the strong MPR₀, responsive to the falling edge of Pφ_{90B}, “post-charges” or resets node Pφ_{0B} to V_{DD} driving Pφ₀ to ground. The PMOS device gated by the static reset signal, RST, of the NOR gate, is made large, and thus, the NOR gate when RST is low has a delay quite close to that of an inverter. One possessing ordinary skill in the art will understand that the NOR gates may be replaced by other combinatorial logic gates while still practicing the present invention.

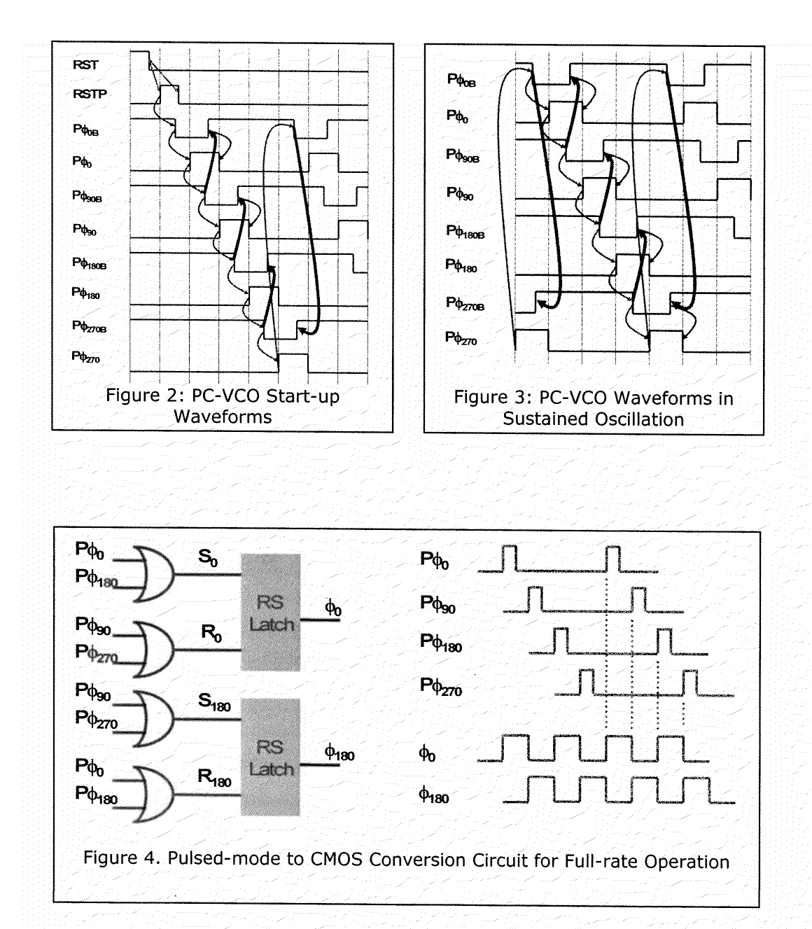

In sequence, and unless RST is asserted, Pφ₀, Pφ₉₀, Pφ₁₈₀, Pφ₂₇₀, Pφ₀, Pφ₉₀, . . . indefinitely generate pulses whose rising edges are precisely spaced by the delay through the pull-down of a weakly-held post-charged node and the succeeding “enabled NOR,” i.e., inverter. FIGS. 2 and 3 show the four-element VCO waveforms from de-assertion of reset and when in sustained oscillation.

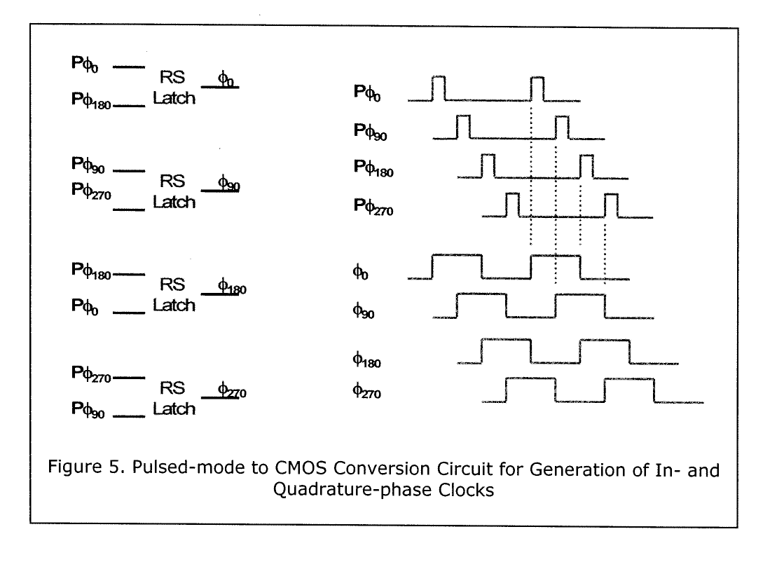

The non-overlapping Pφ₀, Pφ₉₀, Pφ₁₈₀, Pφ₂₇₀ pulses are used to generate the full-rate (FIG. 4) or the In- and Quadrature-phase clocks (FIG. 5). In some implementations where successive pulses partially overlap, a minor modification to the logic of FIG. 4 will yield the same robust outcome.

When the VCO is placed in a PLL loop, V_{CNTL} is adjusted so as to lock the VCO frequency to a multiple of the incoming reference frequency. Instead of a variable V_{CNTL} driving single NMOS devices in the VCO, the circuit can employ a plurality of NMOS devices, a number of which are turned on to adjust the VCO frequency.

The sheer speed advantage of domino circuits over their CMOS counterpart and, in this case, the superior topology of the PC-VCO in comparison to the RO-VCO, allow for significantly lowered supply levels at the same operating frequency.

We claim:

1. A voltage controlled oscillator circuit comprising:
first and second power rails;
a control voltage rail;
an input terminal and an output terminal;
a plurality of domino stages series connected in a ring, each of said domino stages being connected across said first and second power rails and being responsive to said control voltage rail;
a plurality of feedback paths each connected to enable one of said plurality of domino stages to input a feedback output signal to a preceding serially connected domino stage;
at least one of said domino stages responsive to said input terminal; and
at least one of said domino stages being connected to said output terminal.

2. The voltage controlled oscillator circuit in claim 1 further comprising:
a starter circuit for receiving a reset signal and generating a current pulse therefrom, and
wherein said plurality of domino stages receives said reset signal and one of said domino stages receives said current pulse.

3. The voltage controlled oscillator circuit in claim 2, wherein said starter circuit comprises:
a logic circuit for performing a logic NOR operation and having a first input terminal, a second input terminal and an output terminal;
an inverting delay having an input terminal and an output terminal; and
a n-channel field effect transistor having a source terminal, a gate terminal, and a drain terminal;
wherein said first input terminal of said logic circuit and said input terminal of said inverting delay receive said reset signal, said second input terminal of said logic circuit is connected to said output terminal of said inverting delay, and said output terminal of said logic circuit is connected to said gate terminal of said n-channel field effect transistor;
wherein said source terminal of said n-channel field effect transistor is connected to said second power rail; and
wherein said current pulse is available at said drain terminal of said n-channel field effect transistor.

4. The voltage controlled oscillator circuit in claim 2, wherein each of said plurality of domino stages comprises:
a feedback input node; and
a feedback output node, and
wherein each feedback path is connected between the feedback output node of one of said domino stages and the feedback input node of a preceding serially connected domino stage.

5. The voltage controlled oscillator circuit in claim 4, wherein each of said plurality of domino stages comprises:
an input node and an output node;
a p-channel field effect transistor having a source terminal connected to said first power rail, a gate terminal connected to said feedback input node of said domino stage, and a drain terminal;
a first n-channel field effect transistor having a source terminal connected to said second power rail, a gate terminal connected to said input node of said domino stage, and a drain terminal;
a second n-channel field effect transistor having a source terminal connected to said drain terminal of said first n-channel field effect transistor, a drain terminal connected to said drain terminal of said p-channel field effect transistor, and a gate terminal connected to a control voltage node of said domino stage;
wherein said drain terminal of said p-channel field effect transistor and said drain terminal of said second n-channel field effect transistor are connected to said feedback output node of said domino stage; and
a logic element performing a logic NOR operation, comprising a first input terminal for receiving said reset signal and a second input terminal connected to said feedback output node of said domino stage, said logic element having an output terminal connected to said output node of said domino stage.

6. The voltage controlled oscillator circuit in claim 1, additionally comprising:
a plurality of set-reset latches, each of said latches for receiving output signals from a pair of domino stages, each pair of said domino stages being separated by at least one domino stage in said series.

7. The voltage controlled oscillator circuit in claim 1, additionally comprising:
a plurality of logic circuits, each of said logic circuits for receiving output signals from a pair of domino stages being separated by at least one domino stage in said series, and for generating an output signal by performing a logic operation on said received output signals of said domino stages; and
a plurality of set-reset latches responsive to said logic circuits for generating a full-rate differential signal.

8. The voltage controlled oscillator circuit in claim 1, wherein said control voltage rail is configured to receive one of a fixed control voltage or a variable control voltage.

9. A method of generating an oscillating signal, comprising:
inputting to a serially connected ring of domino stages a reset signal to place the domino stages in a post charge state; and
deasserting the reset signal to allow the domino stages to begin producing an oscillating signal.

10. The method in claim 9 wherein a leading edge of a forward output signal activates the next domino stage which, once activated, resets the preceding domino stage via a feedback path and generates its forward output signal.

11. The method in claim 9, additionally comprising combining the forward outputs of a plurality of domino stages to produce edge aligned differential clock signals with a 50% duty cycle.

12. The method in claim 9, additionally comprising combining the forward outputs of four domino stages to produce two pairs of differential clock signals which have an in- and quadrature-phase correlation.
